(19) United States
(12) Patent Application Publication
(10) Pub. No.: US 2008/0095225 A1
(43) Pub. Date: Apr. 24, 2008

(54) System, Multi-Stage Equalizer and Equalization Method

(75) Inventors: Wei-Ting Wang, Yilan City (TW); Ming-Luen Liou, Jhonghe City (TW); Yi-Ching Liao, Taoyuan City (TW)

Correspondence Address: GROSSMAN, TUCKER, PERREAULT & PFLEGER, PLLC, 55 SOUTH COMMERICAL STREET, MANCHESTER, NH, 03101, US

(73) Assignee: MEDIATEK INC., Hsinchu City (TW)

(21) Appl. No.: 11/550,557

(22) Filed: Oct. 18, 2006

(51) Int. Cl. H03H 7/30

(52) U.S. Cl. 375/233

(57) ABSTRACT

A system, a multi-stage equalizer and a method for generating an equalized signal in response to a received signal are provided. The multi-stage equalizer comprises a first DFE, and a second DFE. The first DFE generates a first signal in response to the received signal. The second DFE generates a second signal in response to the first signal, subtracts the second signal from a third signal to generate a fourth signal, and generates the equalized signal in response to the fourth signal, wherein the fourth signal is an unsliced signal. The method comprises steps of: providing a first DFE to generate a first signal in response to the received signal; providing a second DFE to generate a second signal in response to the first signal and to subtract the second signal from a third signal to generate a fourth signal; and generating the equalized signal in response to the fourth signal.

### CROSS-REFERENCES TO RELATED APPLICATIONS

Not applicable

### BACKGROUND OF THE INVENTION

1. Field of the Invention

The present invention relates to a system, a multi-stage equalizer and a method for equalizing a received signal.

2. Descriptions of the Related Art

Ideally, wireless communication systems are designed to transmit and receive signals through an ideal channel without distortion. However, in the real world, distortion during transmission is inevitable. One example of distortion is inter-symbol interference (ISI), which is manifested in the temporal spreading and consequent overlap of individual pulses to the degree that a receiver cannot reliably distinguish between changes of state, i.e., between individual signal elements.

A conventional solution to the ISI is shown in FIG. 1, in which an equalizer 13 is provided in the receiver of the communication system. A signal source 102 is generated by a transmitter of the communication system and sent to a channel 11. During the transmission in the channel 11, the ISI occurs. In other words, the output of the channel 11, or the received signal 104, is the signal source 102 with the ISI. The equalizer 13 then equalizes the received signal 104 to obtain an equalized signal 106. More specifically, the equalizer 13 compensates non-ideal factors of the channel 11 by providing complementary factors. The ISI in the received signal 104, therefore, would be eliminated through the equalizer 13. That is, the equalized signal 106 no longer has the ISI effect.

However, building an equalizer with good performance still remains an issue in this industrial field.

### SUMMARY OF THE INVENTION

An object of the invention is to provide a multi-stage equalizer for generating an equalized signal in response to a received signal. The multi-stage equalizer comprises a first decision feedback equalizer (DFE), and a second DFE. The first DFE is configured to generate a first signal in response to the received signal. The second DFE is configured to generate a second signal in response to the first signal, subtract the second signal from a third signal to generate a fourth signal, and generate the equalized signal in response to the fourth signal. The fourth signal is an unsliced signal.

Another object of the invention is to provide a multi-stage equalizer for generating an equalized signal in response to a received signal. The multi-stage equalizer comprises a first DFE, a filter, and a second DFE. The first DFE is configured to generate a first signal in response to the received signal. The filter outputs a filtered first signal. The second DFE is configured to generate a second signal in response to the filtered first signal, subtract the second signal from a third signal to generate a fourth signal, and generate the equalized signal in response to the fourth signal. The fourth signal is an unsliced signal.

Another object is to provide a method for generating an equalized signal in response to a received signal. The method comprises steps of providing a first DFE to generate a first signal in response to the received signal; providing a second DFE to generate a second signal in response to the first signal and to subtract the second signal from a third signal to generate a fourth signal; and generating the equalized signal in response to the fourth signal.

Another object is to provide a system for generating an equalized signal in response to a received signal. The system comprises a first DFE, a second DFE, and a decoder. The first DFE is configured to generate a first signal in response to the received signal. The second DFE is configured to generate a second signal in response to the first signal, subtract the second signal from a third signal to generate a fourth signal, and generate the equalized signal in response to the fourth signal. The decoder is configured to decode the equalized signal. The fourth signal is an unsliced signal.

Yet a further object is to provide a multi-stage equalizer for generating an equalized signal in response to a received signal. The multi-stage equalizer comprises means for generating a first signal in response to the received signal; and means for generating a second signal in response to the first signal, for subtracting the second signal from a third signal to generate a fourth signal, and for generating the equalized signal in response to the fourth signal.

The present invention provides a multi-stage equalizer with good equalization capability. That is, the ISI effect is greatly reduced.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 shows a block diagram of a conventional transmission system;

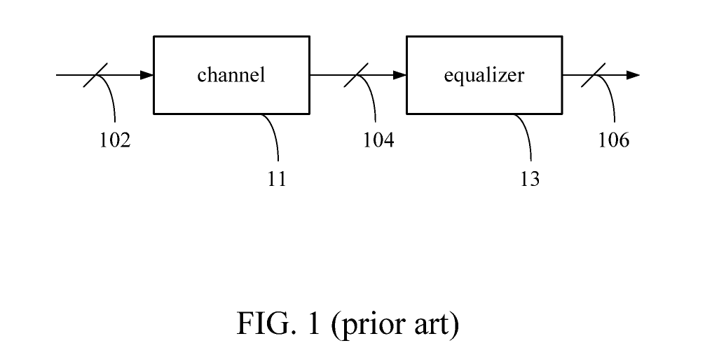

FIG. 2 shows a block diagram of a first embodiment in accordance with the present invention;

FIG. 3 shows a block diagram of an equalizer in accordance with the present invention; and

FIG. 4 shows a flow chart of a second embodiment in accordance with the present invention.

### DESCRIPTION OF THE PREFERRED EMBODIMENT

In this specification, the term “in response to” is defined as “replying to” or “reacting to.” For example, “in response to a signal” means “replying to a signal” or “reacting to a signal” without necessity of direct signal reception.

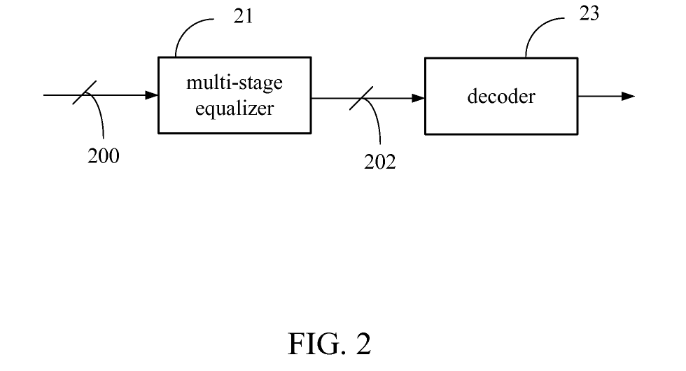

A first embodiment of the present invention is a communication system as shown in FIG. 2. The communication system comprises a multi-stage equalizer 21 and a decoder 23. The multi-stage equalizer 21 receives a received signal 200 to generate an equalized signal 202 that is sent to the decoder 23, wherein the received signal 200 is outputted from a channel (not shown). The decoder 23 then decodes the equalized signal 202 to further remove the ISI for the next stage.

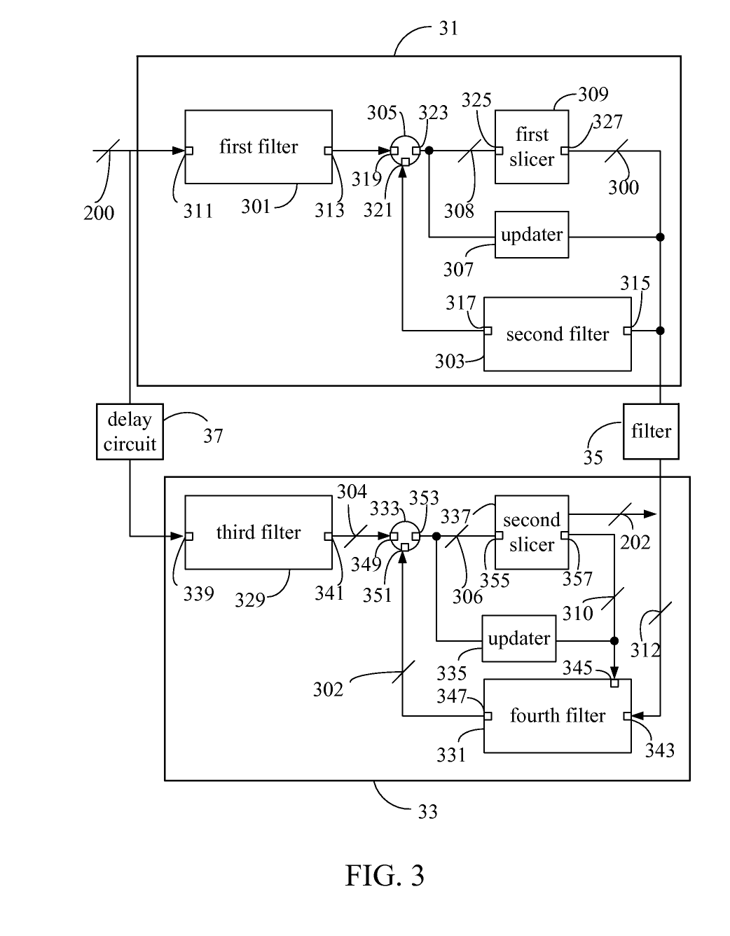

FIG. 3 shows a block diagram of the multi-stage equalizer 21. The multi-stage equalizer 21 comprises a first DFE 31, a second DFE 33, a filter 35, and a delay circuit 37. The first DFE 31 is configured to generate a first signal 300 in response to the received signal 200. The second DFE 33 is configured to generate a second signal 302 in response to the first signal 300, subtract the second signal 302 from a third signal 304 to generate a fourth signal 306, and generate the equalized signal 202 in response to the fourth signal 306.

The first DFE 31 comprises a first filter 301, a second filter 303, a first subtractor 305, an updater 307, and a first slicer 309. The first filter 301, a linear equalizer, comprises an input end 311 and an output end 313. The input end 311 receives the received signal 200. The second filter 303, comprises an input end 315 and an output end 317. The first subtractor 305 comprises a first input end 319, a second input end 321 and an output end 323. The first input end 319 is connected to the output end 313. The second input end 321 is connected to the output end 317. The first slicer 309 comprises an input end 325 and an output end 327. The input end 325 is connected to the output end 323. The output end 327 is connected to the input end 315. The input end 325 carries a fifth signal 308 which is the resulting signal after the signal outputted from the output end 313 is subtracted by the signal outputted from the output end 317 by the first subtractor 305. After sliced by the first slicer 309, the fifth signal 308 becomes the first signal 300 which is transmitted to the input end 315 and the filter 35. The updater 307 is coupled to the input end 325 and the output end 327 to update the coefficients of the first DFE 31.

The second DFE 33 comprises a third filter 329, a fourth filter 331, a second subtractor 333, an updater 335, and a second slicer 337. The third filter 329 comprises an input end 339 and an output end 341. The input end 339 receives the received signal 200 after it is delayed by the delay circuit 37. The fourth filter 331 comprises a first input end 343, a second input end 345, and an output end 347. The second subtractor 333 comprises a first input end 349, a second input end 351 and an output end 353. The first input end 349 is connected to the output end 341. The second signal 302 is carried on the second input end 351. The second slicer 337 comprises an input end 355 and an output end 357. The input end 355 is connected to the output end 353. The output end 357 is connected to the second input end 345. The filter 35 generates a seventh signal 312 after the first signal 300 is filtered. The seventh signal 312 is then carried to the first input end 343. The third signal 304 is generated from the output end 341. The fourth signal 306, an unsliced signal, is carried to the input end 355. After the fourth signal 306 is sliced by the second slicer 337, a sixth signal 310 is generated from the output end 357.

The fourth filter 331 is also a filter which receives the seventh signal 312 and the sixth signal 310. Since the seventh signal 312 is generated after the fifth signal 308 is processed by the first slicer 309 and the filter 35, the second signal 302 is generated in response to the fifth signal 308. Similarly, since the sixth signal 310 is generated after the fourth signal 306 is processed by the second slicer 337, the second signal 302 is generated in response to the fourth signal 306 and the sixth signal 310 as well. More specifically, in the first embodiment, the seventh signal 312 represents a non-causal part of the received signal 200 and the sixth signal 310 represents a causal part of the received signal 200. Based on the non-causal part and the causal part, the second DFE 33 is capable of generating the equalized signal 202 precisely. The effective length of the non-causal part are determined by the delay circuit 37.

The updater 335 is coupled to the input end 355 and the output end 357 to update coefficients of the second DFE 33.

In some embodiments, the filter 35 is not embedded in the communication system. That is, the first signal 300 is transmitted to the first input end 343 directly.

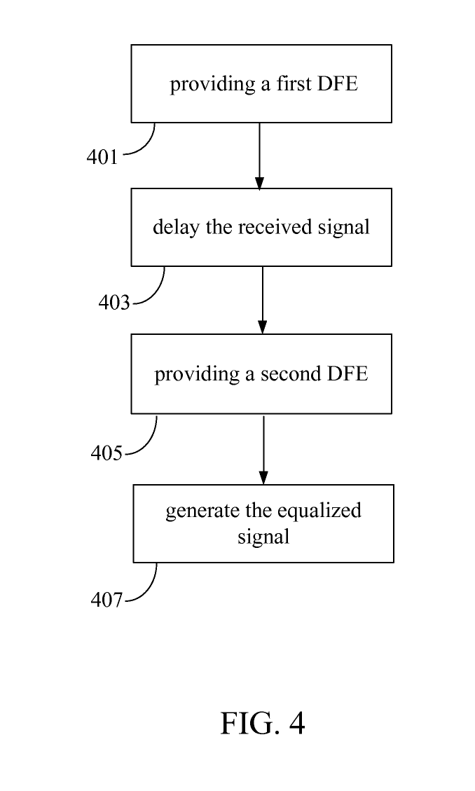

A second embodiment of the present invention is a method adapted for a communication system such as that recited in the first embodiment. The method is for generating an equalized signal in response to a received signal. FIG. 4 shows a flow chart of the second embodiment. In step 401, providing a first DFE to generate a first signal in response to the received signal is executed. The first DFE is similar to the first DFE 31 in the first embodiment. Then, step 403 is executed to delay the received signal. In step 405, providing a second DFE to generate a second signal in response to the first signal and to subtract the second signal from a third signal which is generated in response to the delayed received signal to generate the fourth signal is executed. The second DFE is similar to the second DFE 33 in the first embodiment. Step 407 is then executed to generate the equalized signal in response to the fourth signal.

In addition to the steps shown in FIG. 4, the second embodiment is able to execute all of the operations or functions recited in the first embodiment. Those skilled in the art can straightforwardly realize how the second embodiment performs these operations and functions based on the above descriptions of the first embodiment. Therefore, the descriptions for these operations and functions are redundant and not repeated herein.

The present invention provides a multi-stage equalizer with good equalization capability. More specifically, the multi-stage equalizer, in accordance with the present invention, is capable of taking the non-causal part of the received signal into consideration so the ISI can be further removed.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A multi-stage equalizer for generating an equalized signal in response to a received signal, comprising:
a first decision feedback equalizer (DFE) for generating a first signal in response to the received signal; and
a second DFE for generating a second signal in response to the first signal, for subtracting the second signal from a third signal to generate a fourth signal, and for generating the equalized signal in response to the fourth signal,
wherein the fourth signal is an unsliced signal.

2. The multi-stage equalizer as claimed in claim 1, wherein the first DFE comprises:
a first filter comprising an input end and an output end, the input end receiving the received signal;
a second filter comprising an input end and an output end;
a first subtractor, comprising a first input end, a second input end and an output end, the first input end being connected to the output end of the first filter, the second input end being connected to the output end of the second filter; and
a first slicer comprising an input end and an output end, the input end of the first slicer being connected to the output end of the first subtractor, the output end of the first slicer being connected to the input end of the second filter,
wherein a fifth signal is carried on the input end of the first slicer and the first signal is carried on the output end of the first slicer.

3. The multi-stage equalizer as claimed in claim 2, wherein the first DFE further comprises an updater at least coupled to the input end of the first slicer for updating coefficients of the first DFE.

4. The multi-stage equalizer as claimed in claim 3, wherein the updater adapts the first filter by updating a coefficient of the first filter.

5. The multi-stage equalizer as claimed in claim 3, wherein the updater adapts the second filter by updating a coefficient of the second filter.

6. The multi-stage equalizer as claimed in claim 2, wherein the second DFE comprises:
a third filter comprising an input end and an output end, the input end of the third filter receiving the received signal;
a fourth filter comprising a first input end, a second input end, and an output end;
a second subtractor comprising a first input end, a second input end and an output end, the first input end of the second subtractor being connected to the output end of the third filter, the second signal is carried on the second input end of the second subtractor; and
a second slicer comprising an input end and an output end, the input end of the second slicer being connected to the output end of the second subtractor, the output end of the second slicer being connected to the second input end of the fourth filter.
wherein the first signal is carried on the first input end of the fourth filter, the third signal is carried on the output end of the third filter, the fourth signal is carried on the input end of the second slicer and a sixth signal is carried on the output end of the second slicer.

7. The multi-stage equalizer as claimed in claim 6, wherein the second signal is generated in response to the fourth signal and the fifth signal.

8. The multi-stage equalizer as claimed in claim 6, wherein the second signal is generated in response to the sixth signal.

9. The multi-stage equalizer as claimed in claim 6, wherein the second DFE further comprises an updater at least coupled to the input end of the second slicer for updating coefficients of the second DFE.

10. The multi-stage equalizer as claimed in claim 9, wherein the updater adapts the third filter by updating a coefficient of the third filter.

11. The multi-stage equalizer as claimed in claim 9, wherein the updater adapts the fourth filter by updating a coefficient of the fourth filter.

12. The multi-stage equalizer as claimed in claim 6, further comprising a delay circuit, coupled to the input end of the third filter, for delaying the received signal.

13. A multi-stage equalizer for generating an equalized signal in response to a received signal, comprising:
a first decision feedback equalizer (DFE) for generating a first signal in response to the received signal;
a filter to output a filtered first signal; and
a second DFE for generating a second signal in response to the filtered first signal, for subtracting the second signal from a third signal to generate a fourth signal, and for generating the equalized signal in response to the fourth signal,
wherein the fourth signal is an unsliced signal.

14. A method for generating an equalized signal in response to a received signal, comprising steps of:
providing a first DFE to generate a first signal in response to the received signal;
providing a second DFE to generate a second signal in response to the first signal and to subtract the second signal from a third signal to generate a fourth signal; and
generating the equalized signal in response to the fourth signal.

15. The method as claimed in claim 14, wherein the step of providing a first DFE comprises steps of:
providing a first filter, the first filter comprising an input end and an output end, the input end receiving the received signal;
providing a second filter, the second filter comprising an input end and an output end;
providing a first subtractor, the first subtractor comprising a first input end, a second input end and an output end, the first input end being connected to the output end of the first filter, the second input end being connected to the output end of the second filter; and
providing a first slicer, the first slicer comprising an input end and an output end, the input end of the first slicer being connected to the output end of the subtractor, the output end of the first slicer being connected to the input end of the second filter,
wherein a fifth signal is carried on the input end of the first slicer and the first signal is carried on the output end of the first slicer.

16. The method as claimed in claim 15, wherein the step of providing a first DFE comprises a step of providing an updater at least coupled to the input end of the first slicer for updating coefficients of the first DFE.

17. The method as claimed in claim 16, further comprising a step of adapting the first filter by updating a coefficient of the first filter.

18. The method as claimed in claim 16, further comprising a step of adapting the second filter by updating a coefficient of the second filter.

19. The method as claimed in claim 15, wherein the step of providing a first equalizer comprises steps of:
providing a third filter, the third filter comprising an input end and an output end, the input end of the third filter receiving the received signal;
providing a fourth filter, the fourth filter comprising a first input end, a second input end, and an output end;
providing a second subtractor, the second subtractor comprising a first input end, a second input end and an output end, the first input end of the second subtractor being connected to the output end of the third filter, the second signal is carried on the second input end of the second subtractor; and
providing a second slicer, the second slicer comprising an input end and an output end, the input end of the second slicer being connected to the output end of the second subtractor, the output end of the second slicer being connected to the second input end of the fourth filter,
wherein the first signal is carried on the first input end of the fourth filter, the third signal is carried on the output end of the third filter, the fourth signal is carried on the input end of the second slicer and a sixth signal is carried on the output end of the second slicer.

20. The method as claimed in claim 19, wherein the second signal is generated in response to the fourth signal and the fifth signal.

21. The method as claimed in claim 19, wherein the second signal is generated in response to the sixth signal.

22. The method as claimed in claim 19, further comprising a step of updating a coefficient of the first equalizer.

23. The method as claimed in claim 22, further comprising a step of updating a coefficient of the third filter.

24. The method as claimed in claim 22, further comprising a step of updating a coefficient of the fourths filter.

25. The method as claimed in claim 19, further comprising a step of delaying the received signal before the received signal reaches the input end of the third filter.

26. A system for generating an equalized signal in response to a received signal, comprising:
a first decision feedback equalizer (DFE) for generating a first signal in response to the received signal; and
a second DFE for generating a second signal in response to the first signal, for subtracting the second signal from a third signal to generate a fourth signal, and for generating the equalized signal in response to the fourth signal; and
a decoder for decoding the equalized signal;
wherein the fourth signal is an unsliced signal.

27. A multi-stage equalizer for generating an equalized signal in response to a received signal, comprising:
means for generating a first signal in response to the received signal; and
means for generating a second signal in response to the first signal, for subtracting the second signal from a third signal to generate a fourth signal, and for generating the equalized signal in response to the fourth signal.
